(19) United States
(12) Patent Application Publication
(10) Pub. No.: US 2026/0188926 A1
(43) Pub. Date: Jul. 2, 2026

(54) ELECTRONIC COMPONENT, TERMINAL STRUCTURE FOR ELECTRONIC COMPONENT, AND ELECTRONIC DEVICE

(71) Applicant: Tokyo Cosmos Electric Co., Ltd., Kanagawa (JP)

(72) Inventor: Hajime FUKUSHIMA, Kanagawa (JP)

(73) Assignee: Tokyo Cosmos Electric Co., Ltd., Kanagawa (JP)

(21) Appl. No.: 18/857,471

(22) PCT Filed: Apr. 18, 2023
(86) PCT No.: PCT/JP2023/015413

§ 371 Date: Oct. 17, 2024

(30) Foreign Application Priority Data
Apr. 22, 2022 (JP) 2022-070862

(51) Int. Cl. H01R 12/71; H01R 13/24; H01R 13/66; H05K 7/12

(52) U.S. Cl. CPC H01R 12/714; H01R 13/245; H01R 13/665; H05K 7/12

(57) ABSTRACT

This electronic component, terminal structure for an electronic component, and electronic device prevent the occurrence of environmental impact by not using solder, reduce assembly costs, and make it possible to lighten the load on an electrical connection section. One embodiment of the present invention is an electronic component comprising an electronic component body and a conductive terminal, wherein the terminal is a leaf spring having elasticity, a central section of the leaf spring in the lengthwise direction has a supported section supported so as to be sandwiched by both groove walls of a groove provided to the electronic component body, and at least one end of the two ends of the leaf spring in the lengthwise direction is in contact in an elastically deformed state with a printed circuit board.

### TECHNICAL FIELD

The present invention relates to an electronic component, an electronic component terminal structure, and an electronic apparatus.

### BACKGROUND ART

It has been known that soldering is performed to connect between a terminal of an electronic component and a printed circuit board.

In a case where the soldering is performed by a soldering robot, the facility cost increases. Further, in a case where the soldering is performed by an operator, the number of man-hours in the soldering work increases. For this reason, there is a problem of the high assembly cost. Further, there is also a problem in that an environmental load is generated by using solder.

Further, Patent Literature (hereinafter referred to as “PTL”) 1 discloses an electronic apparatus including two contact members that are disposed to face each other and a coil spring that is disposed between the two contact members, in which end portions of the coil spring are welded respectively to the two contact members with a conductive adhesive.

### CITATION LIST

### Patent Literature

### PTL 1

Japanese Patent Application Laid-Open No. 2000-243167

### SUMMARY OF INVENTION

### Technical Problem

In the electronic apparatus described in PTL 1, when the end portions of the coil spring are welded respectively to the contact members with the conductive adhesive, the coil spring is held in a predetermined position with, for example, a jig, and then the welding is performed, thus taking the man-hours as in the soldering work. This causes a problem of the high assembly cost.

Further, for example, application of an impact or the like to an electronic component causes a problem in that a load is applied to an electrical connection portion subjected to soldering or an electrical connection portion welded by a conductive adhesive.

An object of the present invention is to provide an electronic component, a terminal structure of an electronic component, and an electronic apparatus each capable of preventing an environmental load, reducing the assembly cost, and reducing a load on an electrical connection portion, by not using solder.

### Solution to Problem

To achieve the above-described object, an electronic component according to the present invention includes: an electronic component main body; and a terminal that has conductivity, in which: the terminal is a leaf spring that has elasticity, a central portion of the leaf spring in a longitudinal direction includes a supported portion that is supported to be held between both groove walls of a groove provided in the electronic component main body, and at least one end portion of both end portions of the leaf spring in the longitudinal direction is in contact with a printed circuit board in an elastically deformed state.

An electronic component terminal structure according to the present invention is a terminal structure of an electronic component including an electronic component main body, the terminal structure including a terminal that has conductivity, in which: the terminal is a leaf spring that has elasticity, a central portion of the leaf spring in a longitudinal direction includes a supported portion that is held between both groove walls of a groove provided in the electronic component main body, and at least one end portion of both end portions of the leaf spring in the longitudinal direction is in contact with a printed circuit board in an elastically deformed state.

An electronic apparatus according to the present invention includes: the above-described electronic component; a case that houses the above-described electronic component; and a printed circuit board.

### Advantageous Effects of Invention

According to the present invention, it is possible to reduce the assembly cost and to reduce the load on an electrical connection portion.

### BRIEF DESCRIPTION OF DRAWINGS

FIG. 1 is an overall view of an electronic component according to an embodiment of the present invention, illustrating a part of the electronic component in cross section;

FIG. 2 is a cross-sectional view taken along line A-A of FIG. 1;

FIG. 3 is an overall view of an electronic component according to a variation, illustrating a part of the electronic component in cross section; and

FIG. 4 is a cross-sectional view taken along line B-B of FIG. 3.

### DESCRIPTION OF EMBODIMENTS

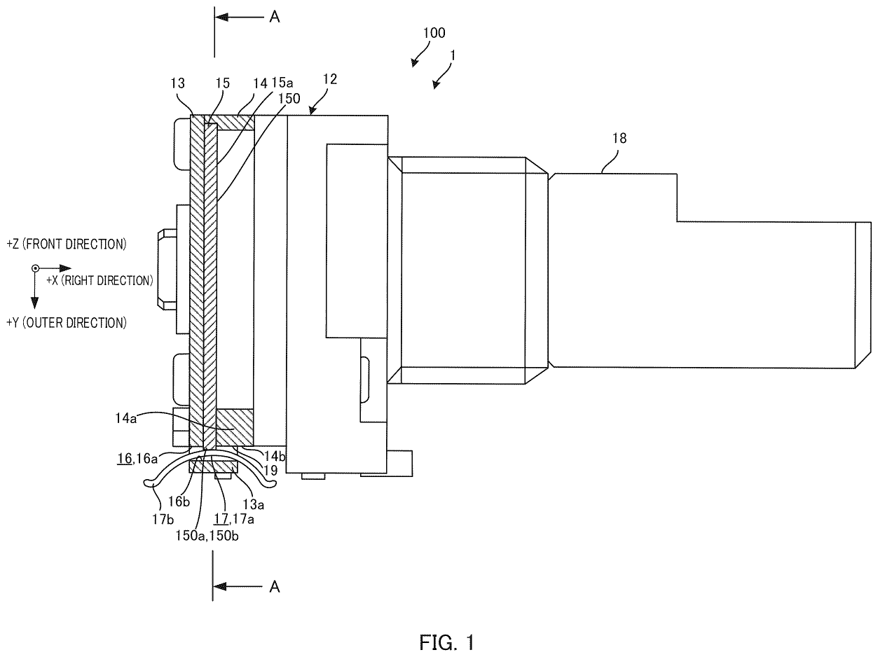

Hereinafter, an embodiment of the present invention will be described with reference to the drawings. FIG. 1 is an overall view of an electronic component according to an embodiment of the present invention, illustrating a part of the electronic component in cross section. FIG. 1 illustrates an X axis, a Y axis, and a Z axis. In FIG. 1, a right-left direction will be referred to as an X direction, a right direction will be referred to as a right side or a “+X direction,” and a left direction will be referred to as a left side or a “−X direction.” Further, an up-down direction in FIG. 1 is referred to as an inside-outside direction or a Y direction, and a direction moving away from the X axis along the Y axis is referred to as an outer direction, an outside, an outer side, or a “+Y direction,” and a direction approaching the X axis along the Y axis is referred to as an inner direction, an inside, an inner side, or a “−Y direction.” Further, a direction orthogonal to the plane in FIG. 1 will be referred to as a depth direction or a Z direction, a front direction is referred to as a “+Z direction,” and a rear direction is referred to as a “−Z direction.”

Electronic apparatus 100 in the present embodiment includes electronic component 1, a case (not illustrated), and a printed circuit board (not illustrated). In the present embodiment, electronic component 1 is a potentiometer that outputs a voltage corresponding to a mechanical displacement amount of the rotation of an input shaft, or a rotary encoder that converts the mechanical displacement amount of the rotation of the input shaft into a digital amount.

As illustrated in FIG. 1, electronic component 1 includes electronic component main body 12 and leaf spring 17. Electronic component main body 12 includes a shaft bearing (not illustrated) that rotatably supports input shaft 18.

Electronic component main body 12 includes first main body portion 13, second main body portion 14, resistance substrate 15, and holding groove 19. First main body portion 13 is disposed on the left side (−X direction) relative to second main body portion 14. Resistance substrate 15 is disposed between first main body portion 13 and second main body portion 14.

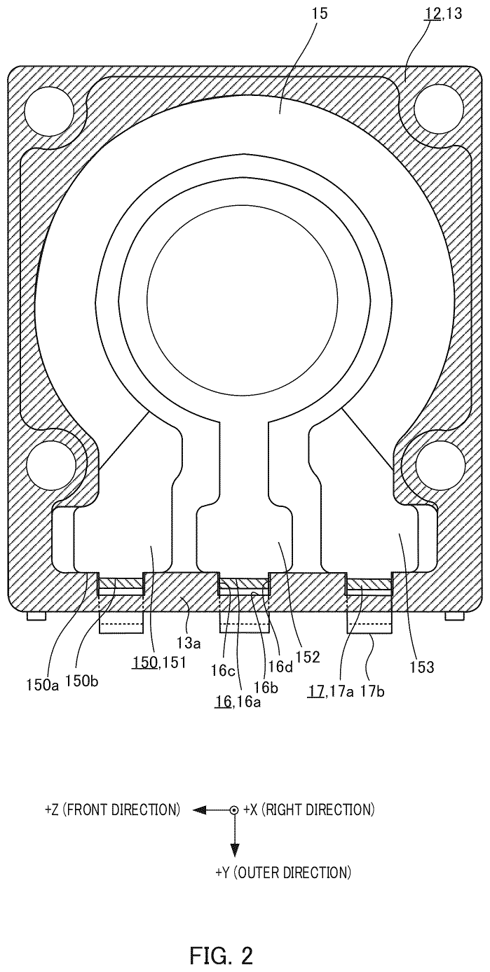

FIG. 2 is a cross-sectional view taken along line A-A of FIG. 1. As illustrated in FIG. 2, first main body portion 13 includes a rectangular frame portion. The frame portion includes outer-side edge portion 13a (lower-side edge portion illustrated in FIG. 2). Outer-side edge portion 13a includes through-hole 16 that penetrates in the right-left direction. Through-hole 16 includes inner-side hole wall 16a and outer-side hole wall 16b that is located in the outer direction (+Y direction) relative to inner-side hole wall 16a, and faces inner-side hole wall 16a in the inside-outside direction (Y direction). Further, through-hole 16 includes front-side hole wall 16c, and rear-side hole wall 16d that is located on the rear side (−Z direction) relative to front-side hole wall 16c and faces front-side hole wall 16c in the depth direction (Z direction).

Second main body portion 14 includes a rectangular frame portion. The frame portion includes outer-side edge portion 14a (lower-side edge portion illustrated in FIG. 1). Outer-side edge portion 14a includes outside wall 14b that faces in the outer direction (+Y direction). Outside wall 14b is located at substantially the same position as inner-side hole wall 16a in the inside-outside direction (Y direction).

FIG. 2 is a front view of a terminal structure of electronic component 1. As illustrated in FIGS. 1 and 2, each of a plurality of electrode patterns 150 is fixed to right-side wall surface 15a of resistance substrate 15. Note that each of the plurality of electrode patterns 150 is formed to extend to a lower end portion of resistance substrate 15. The plurality of electrode patterns 150 each includes input electrode pattern 151, output electrode pattern 152, and ground electrode pattern 153. Outer end portion 150a (lower end portion illustrated in FIG. 2) of each of the plurality of electrode patterns 150 includes protruding portion 150b.

Holding groove 19 includes both groove walls that face each other in the inside-outside direction (Y direction). An inner-side groove wall of the both groove walls is constituted by inner-side hole wall 16a, outside wall 14b, and protruding portion 150b, protruding portion 150b is disposed between inner-side hole wall 16a and outside wall 14b, and is provided to be protruded on an inner side of holding groove 19 relative to inner-side hole wall 16a and outside wall 14b.

An outer-side groove wall of the both groove walls is constituted by outer-side hole wall 16b. That is, the outer-side groove wall (outer-side hole wall 16b) of the both groove walls is disposed to face the inner-side groove wall (inner-side hole wall 16a, outside wall 14b, and protruding portion 150b) of the both groove walls in the inside-outside direction (Y direction).

The both groove walls that face each other in the depth direction (Z direction) are constituted by front-side hole wall 16c and rear-side hole wall 16d of through-hole 16. The difference between a distance in the depth direction (Z direction) from front-side hole wall 16c to rear-side hole wall 16d and a length of leaf spring 17 in the depth direction is set to be small.

The distance between the both groove walls that face each other in the inside-outside direction (Y direction), and the distance between both groove walls that face each other in the depth direction (Z direction) are distances in which leaf spring 17 can pass through holding groove 19 in a longitudinal direction.

As illustrated in FIG. 2, three holding grooves 19 are disposed respectively to outer end portions 150a (lower end portions in FIG. 2) of the plurality of electrode patterns 150. Three holding grooves 19 have the same configuration as each other. Further, leaf spring 17 supported by each of three holding grooves 19 has the same configuration as each other.

Hereinafter, one holding groove 19 and one leaf spring 17 supported by holding groove 19 will be representatively described. Leaf spring 17 has elasticity. Leaf spring 17 is a terminal having conductivity. Leaf spring 17 is curved in an arc shape along the longitudinal direction. A central portion of leaf spring 17 in the longitudinal direction includes supported portion 17a.

Supported portion 17a of leaf spring 17 is in contact with protruding portion 150b provided at outer end portion 150a of electrode pattern 150 (lower end portion in FIG. 2).

Further, supported portion 17a is in contact with outer-side hole wall 16b. That is, supported portion 17a is supported to be held between protruding portion 150b and outer-side hole wall 16b in the inside-outside direction (Y direction). Thus, leaf spring 17 is supported so as not to come off from holding groove 19.

Further, movement of leaf spring 17 in the longitudinal direction is limited by a friction resistance force generated between supported portion 17a and protruding portion 150b and a friction resistance force generated between supported portion 17a and outer-side hole wall 16b.

Further, since the distance in the depth direction (Z direction) between front-side hole wall 16c and rear-side hole wall 16d of through-hole 16 is slightly different from the length of leaf spring 17 in the depth direction (Z direction), movement of leaf spring 17 in the depth direction (Z direction) and rotation around supported portion 17a are limited.

At the time of assembly of electronic apparatus 100, both end portions 17b of leaf spring 17 in the longitudinal direction are brought into contact with a printed circuit board (not illustrated). Thus, leaf spring 17 is brought into an elastically deformed state

Next, an example of an method of assembling of electronic apparatus 100 will be described briefly. First, a description will be given of an assembly method of electronic component 1. Note that, at the time of assembly of electronic apparatus 100, a case (not illustrated) is disposed in the upward direction in FIG. 1 of electronic component 1, and a printed circuit board (not illustrated) is disposed in the downward direction in FIG. 1 of electronic component 1.

First, resistance substrate 15 is disposed at a predetermined position in first main body portion 13 from the right direction (+X direction).

Next, second main body portion 14 is disposed to face the predetermined position in first main body portion 13 from the right direction (+X direction) and is assembled with first main body portion 13.

Next, leaf spring 17 is passed through holding groove 19 from, for example, the left direction (−X direction) to match positions of supported portion 17a and protruding portion 150b with each other. Thus, supported portion 17a is supported to be held between protruding portion 150b and outer-side hole wall 16b in the inside-outside direction (Y direction). Electronic component 1 is thus assembled. When supported portion 17a is s supported to be held between holding grooves 19, leaf spring 17 does not come off from electronic component main body 12, and thus, electronic component 1 can be easily handled.

Next, assembled electronic component 1 is disposed at a predetermined position in the case (not illustrated) from the downward direction in FIG. 1.

Next, the printed circuit board (not illustrated) is disposed at a predetermined position in the case from the downward direction in FIG. 1.

Next, the case and the printed circuit board are assembled by a joining member (for example, screw). This causes a situation where electronic component 1 is held between the case and the printed circuit board, and thus, leaf spring 17 is brought into a state of being pressed against and contracted by the printed circuit board. In a state in which leaf spring 17 is contracted, both end portions 17b of leaf spring 17 in the longitudinal direction are in contact with the printed circuit board. Further, supported portion 17a (central portion in longitudinal direction) of leaf spring 17 is in contact with outer end portion 150a of each of the plurality of electrode patterns 150. The electrical connection portion connecting between supported portion 17a of leaf spring 17 and outer end portion 150a of electrode pattern 150 is an electrical connection portion not subjected to soldering. Further, the electrical connection portion connecting between both end portions 17b of leaf spring 17 and the printed circuit board is an electrical connection portion not subjected to soldering.

Electronic component 1 according to the present embodiment includes electronic component main body 12 and a terminal having conductivity, in which the terminal is leaf spring 17 having elasticity, a central portion of leaf spring 17 in a longitudinal direction includes supported portion 17a that is supported to be held between both groove walls of holding groove 19 provided in electronic component main body 12, and at least one end portion 17b of both end portions of leaf spring 17 in the longitudinal direction comes into contact with a printed circuit board in an elastically deformed state.

With the above configuration, when leaf spring 17 is brought into contact with the printed circuit board in a contracted state, an electrical connection portion connecting between leaf spring 17 and the printed circuit board is formed, which eliminates the need for an electrical connection portion subjected to soldering, thereby reducing the assembly cost and reducing the load on the electrical connection portion.

Further, by supporting supported portion 17a such that supported portion 17a is supported to be heled between both groove walls of holding groove 19, leaf spring 17 does not come off from electronic component main body 12, and thus, it is possible to easily handle electronic component 1 and to increase the transportability of electronic component 1.

Further, electronic component 1 according to the above embodiment further includes resistance substrate 15 that has a plurality of electrode patterns 150, in which a plurality of leaf springs 17 disposed respectively at positions of the plurality of electrode patterns 150, and supported portion 17a of each of the plurality of leaf springs 17 is in contact with corresponding one of the plurality of electrode patterns 150. Thus, an electrical connection portion connecting between leaf spring 17 and the printed circuit board is formed, which eliminates the need for an electrical connection portion subjected to soldering, thereby reducing the assembly cost and reducing the load on the electrical connection portion.

Further, in electronic component 1 according to the above embodiment, each of the plurality of electrode patterns 150 includes protruding portion 150b that is provided to be protruded from at least one groove wall of both groove walls of holding groove 19 toward an inner side of the holding groove 19. Thus, since a central portion of leaf spring 17 in the longitudinal direction is easily brought into contact with protruding portion 150b, it is possible to enhance the connection stability in the electrical connection portion.

Further, in electronic component 1 according to the above embodiment, supported portion 17a of each of the plurality of leaf springs 17 is in contact with protruding portion 150b. This causes supported portion 17a to be pushed into protruding portion 150b, and force for supporting supported portion 17a is accordingly increased, thereby surely preventing leaf spring 17 from coming off from holding groove 19.

### (Variation)

Next, a variation of electronic component 1 according to the present embodiment will be described. Note that, in the description of the following variation, configurations different from those in the above embodiment will be mainly described, whereas the identical components are given the same reference numerals, and the descriptions thereof will be omitted.

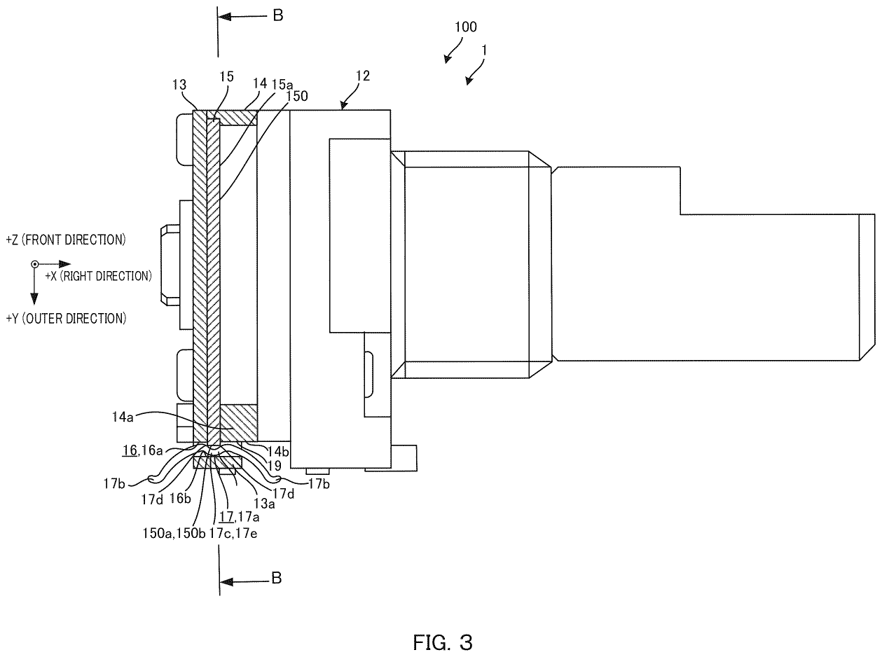

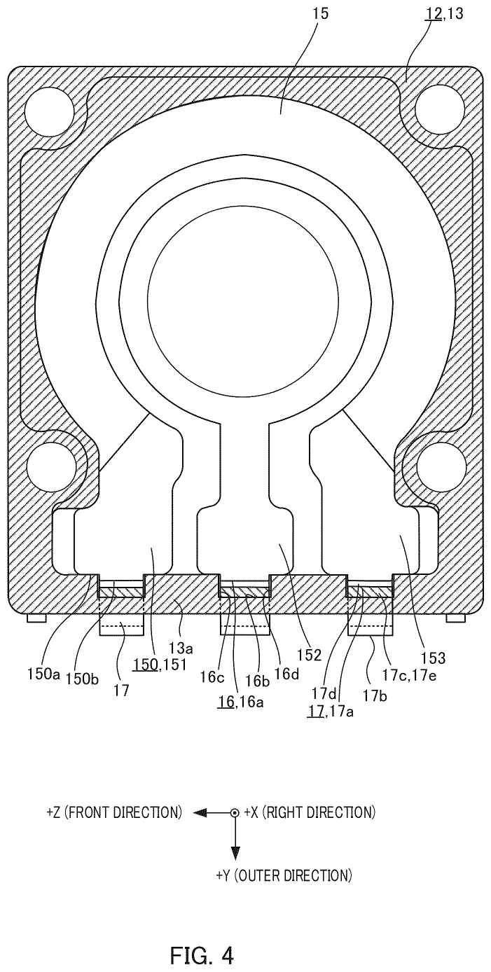

First, electronic component 1 according to a variation will be described with reference to FIGS. 3 and 4. FIG. 3 is an overall view of an electronic component according to a variation, illustrating a part of the electronic component in cross section. FIG. 4 is a cross-sectional view taken along line B-B of FIG. 3.

In the above embodiment, supported portion 17a of leaf spring 17 is in contact with protruding portion 150b provided at outer end portion 150a of each of the plurality of electrode patterns 150.

In contrast, in the variation, as illustrated in FIGS. 3 and 4, supported portion 17a includes recessed portion 17c fits on protruding portion 150b. Recessed portion 17c is a recess having a U-shaped cross-sectional shape and includes both standing walls 17d and bottom wall 17e. Both standing walls 17d face each other in the right-left direction, and protruding portion 150b is fitted between both standing walls. Thus, it is possible to limit the movement of leaf spring 17 in the right-left direction (longitudinal direction).

Further, as illustrated in FIG. 3, each of both standing walls 17d is in contact with protruding portion 150b, and bottom wall 17e is in contact with outer-side hole wall 16b. A central portion position of a position of a location at which each of both standing walls 17d is in contact with protruding portion 150b in the right-left direction (X direction) is a position of a location at which bottom wall 17e is in contact with outer-side hole wall 16b in the right-left direction (X direction). Thus, since supported portion 17a is stably supported by holding groove 19, it is possible to achieve the connection stability in an electrical connection portion.

In the above embodiment and variation, the inner-side groove wall of the both groove walls of holding groove 19 is constituted by inner-side hole wall 16a, outside wall 14b, and protruding portion 150b, and the outer-side groove wall of the both groove walls of holding groove 19 is constituted by outer-side hole wall 16b. However, the holding groove according to the present invention is not limited to this. Any holding groove is possible as long as it supports leaf spring 17 in a holding manner and is constituted by a component that constitutes electronic component 1 (such as electronic component main body 12 or resistance substrate 15) according to the shape of leaf spring 17.

In addition, in the above embodiment and variation, protruding portion 150b is provided at outer end portion 150a of electrode pattern 150, and supported portion 17a of leaf spring 17 is in contact with protruding portion 150b. However, outer end portion 150a of electrode pattern 150 is not limited to this. For example, the inner-side groove wall of the both groove walls of holding groove 19 may be constituted by inner-side hole wall 16a, outside wall 14b, and outer end portion 150a of electrode pattern 150, and outer end portion 150a of electrode pattern 150 may be located at substantially the same position as inner-side hole wall 16a and outside wall 14b in the inside-outside direction (Y direction), and supported portion 17a may be brought into contact with outer end portion 150a of electrode pattern 150.

The embodiment and variations described above are merely examples of specific implementation of the present invention, and the technical scope of the present invention should not be restrictively interpreted by these embodiments. That is, the present invention may be implemented in various forms without departing from the spirit thereof or the major features thereof.

This application is based on Japanese patent application No. 2022-070862, filed Apr. 22, 2022, the contents of which are incorporated herein by reference.

### INDUSTRIAL APPLICABILITY

The present invention is suitably utilized in an electronic apparatus including an electronic component, which is required to reduce the assembly cost and to reduce the load on an electrical connection portion.

### REFERENCE SIGNS LIST

1 Electronic component
12 Electronic component main body
13 First main body portion
13a Outer-side edge portion
14 Second main body portion
14a Outer-side edge portion
14b Outside wall
15 Resistance substrate
15a Right-side wall surface
150 Electrode pattern
150a Outer end portion
150b Protruding portion
151 Input electrode pattern
152 Output electrode pattern
153 Ground electrode pattern
16 Through-hole
16a Inner-side hole wall
16b Outer-side hole wall
16c Front-side hole wall
16d Rear-side hole wall
17 Leaf spring
17a Supported portion
17b End portion
17c Recessed portion
17d Standing wall
17e Bottom wall
18 Input shaft
19 Holding groove
100 Electronic apparatus

1. An electronic component, comprising:
an electronic component main body; and
a terminal that has conductivity,
wherein:
the terminal is a leaf spring that has elasticity,
a central portion of the leaf spring in a longitudinal direction includes a supported portion that is supported to be held between both groove walls of a groove provided in the electronic component main body, and
at least one end portion of both end portions of the leaf spring in the longitudinal direction is in contact with a printed circuit board in an elastically deformed state.

2. The electronic component according to claim 1, further comprising a resistance substrate that has a plurality of electrode patterns,
wherein:
a plurality of the leaf springs are disposed respectively at positions of the plurality of electrode patterns, and
the supported portion of each of the plurality of leaf springs is in contact with corresponding one of the plurality of electrode patterns.

3. The electronic component according to claim 2, wherein each of the plurality of electrode patterns includes a protruding portion that is provided to be protruded from at least one groove wall of the both groove walls toward an inner side of the groove.

4. The electronic component according to claim 3, wherein the supported portion of each of the plurality of leaf springs is in contact with the protruding portion.

5. The electronic component according to claim 4, wherein the supported portion includes a recessed portion that fits to the protruding portion.

6. A terminal structure of an electronic component including an electronic component main body, the terminal structure comprising:
a terminal that has conductivity,
wherein:
the terminal is a leaf spring that has elasticity,
a central portion of the leaf spring in a longitudinal direction includes a supported portion that is held between both groove walls of a groove provided in the electronic component main body, and
at least one end portion of both end portions of the leaf spring in the longitudinal direction is in contact with a printed circuit board in an elastically deformed state.

7. An electronic apparatus, comprising:
the electronic component according to claim 1,
a case that houses the electronic component; and
a printed circuit board.
